(19) United States
(12) Patent Application Publication
(10) Pub. No.: US 2026/0019042 A1
(43) Pub. Date: Jan. 15, 2026

(54) DOHERTY AMPLIFIER CIRCUIT AND AMPLIFIER

(71) Applicant: Murata Manufacturing Co., Ltd., Nagaokakyo-shi (JP)

(72) Inventor: Shohei IMAI, Nagaokakyo-shi (JP)

(21) Appl. No.: 19/332,294

(22) Filed: Sep. 18, 2025

Related U.S. Application Data
(63) Continuation of application No. PCT/JP2024/003731, filed on Feb. 5, 2024.

(30) Foreign Application Priority Data
Mar. 31, 2023 (JP) 2023-058637

(51) Int. Cl. H03F 1/02; H03F 3/24

(52) U.S. Cl. CPC H03F 1/0288; H03F 3/245; H03F 2200/451

(57) ABSTRACT

A Doherty amplifier circuit includes a carrier amplifier that amplifies a radio-frequency signal, a peak amplifier that amplifies a radio-frequency signal, and a bias circuit that supplies a bias current or a bias voltage to the peak amplifier. The peak amplifier includes one or more amplifier transistors that amplify a radio-frequency signal, and a state control circuit that controls the operating state of the one or more amplifier transistors on the basis of an input control signal.

### CROSS REFERENCE TO RELATED APPLICATION

This is a continuation of International Application No. PCT/JP2024/003731 filed on Feb. 5, 2024 which claims priority from Japanese Patent Application No. 2023-058637 filed on Mar. 31, 2023. The contents of these applications are incorporated herein by reference in their entireties.

### BACKGROUND OF THE DISCLOSURE

### Field of the Disclosure

The present disclosure relates to a Doherty amplifier circuit and an amplifier.

### Description of the Related Art

Doherty amplifier circuits are known as high-efficiency power amplifier circuits. Typically, a Doherty amplifier circuit has a configuration in which a carrier amplifier, which operates regardless of the power level of an input signal, is connected in parallel to a peak amplifier, which is switched off when the power level of an input signal is low and which is switched on when the power level is high. In the configuration, when the power level of a radio-frequency input signal is high, the carrier amplifier operates while maintaining saturation at the saturated output-power level. Thus, the Doherty amplifier circuit achieves improvement of efficiency compared with a normal power amplifier circuit.

U.S. Patent Application Publication No. 2016/0241209 listed below describes a technique which controls a bias for a peak amplifier. In the technique described in U.S. Patent Application Publication No. 2016/0241209, saturation of a carrier amplifier is detected through a bias circuit for the carrier amplifier, and a bias circuit for the peak amplifier is controlled in accordance with the detection signal.

### BRIEF SUMMARY OF THE DISCLOSURE

In the technique described in U.S. Patent Application Publication No. 2016/0241209, it takes about several tens of ns to make a response by a circuit for detecting saturation of the carrier amplifier. Therefore, the following disadvantage may occur. For example, when a Doherty amplifier circuit receives a radio-frequency input signal with a momentary (well below several tens of ns) power increase, a time for which the carrier amplifier is saturated may occur in the several tens of ns which is the time period after the carrier amplifier starts becoming saturated until the bias point for the peak amplifier is changed. This may cause failure to maintain high quality of a radio-frequency output signal of the Doherty amplifier circuit. In addition, when the Doherty amplifier circuit is applied to a communication device, high communication quality may fail to be maintained.

The present disclosure is made in view of the situation described above, and a possible benefit thereof is to suppress a decrease of the quality of a radio-frequency output signal.

A Doherty amplifier circuit according to an aspect of the present disclosure includes a carrier amplifier that amplifies a radio-frequency signal; a peak amplifier that amplifies a radio-frequency signal; and a bias circuit that supplies a bias current or a bias voltage to the peak amplifier. The peak amplifier includes one or more amplifier transistors that amplify a radio-frequency signal, and a state control circuit that controls an operating state of the one or more amplifier transistors on the basis of an input control signal.

An amplifier according to an aspect of the present disclosure includes one or more amplifier transistors that amplify a radio-frequency signal; a bias circuit that supplies a bias current or a bias voltage to the one or more amplifier transistors; and a state control circuit that controls an operating state of the one or more amplifier transistors on the basis of an input control signal.

According to the present disclosure, a decrease of the quality of a radio-frequency output signal may be suppressed.

### BRIEF DESCRIPTION OF THE SEVERAL VIEWS OF THE DRAWINGS

FIG. 1 is a diagram illustrating the configuration of a Doherty amplifier circuit according to a first embodiment.

FIG. 2 is a diagram illustrating the configuration of a peak amplifier according to a second embodiment.

FIG. 3 is a diagram illustrating the configuration of a peak amplifier according to a first modified example of the second embodiment.

FIG. 4 is a diagram illustrating the configuration of a peak amplifier according to a second modified example of the second embodiment.

FIG. 5 is a diagram illustrating the configuration of a detector circuit according to a third embodiment.

FIG. 6 is a diagram illustrating the configuration of a Doherty amplifier circuit according to a fourth embodiment.

FIG. 7 is a diagram illustrating the configuration of a Doherty amplifier circuit according to a fifth embodiment.

FIG. 8 is a diagram illustrating the configuration of a Doherty amplifier circuit according to a sixth embodiment.

FIG. 9 is a diagram illustrating the configuration of a Doherty amplifier circuit according to a seventh embodiment.

### DETAILED DESCRIPTION OF THE DISCLOSURE

Embodiments of the present disclosure will be described in detail below on the basis of the drawings. The embodiments do not limit the present disclosure. Needless to say, the embodiments are exemplary, and partial replacement or combination of configurations illustrated in different embodiments may be made. In a second embodiment and its subsequent embodiments, points common to those in a first embodiment will not be described, and only different points will be described. In particular, substantially the same operational effects caused by substantially the same configuration will not be described in each embodiment.

### First Embodiment

### (Configuration)

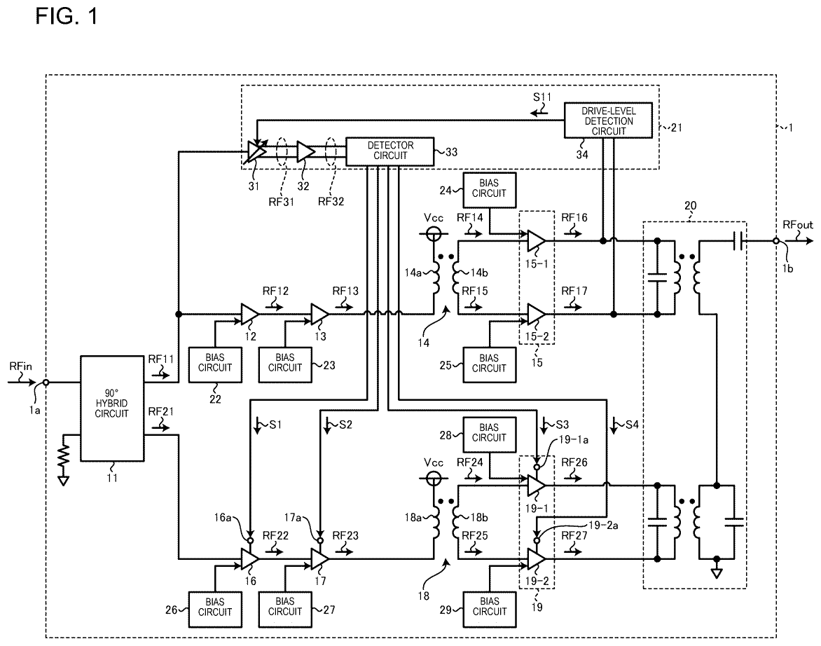

FIG. 1 is a diagram illustrating the configuration of a Doherty amplifier circuit according to the first embodiment. A Doherty amplifier circuit 1 amplifies a radio-frequency signal RFin received at an input terminal 1a, and outputs a radio-frequency signal RFout from an output terminal 1b.

The Doherty amplifier circuit 1 includes a 90° hybrid circuit 11, an initial-stage (driver-stage) carrier amplifier 12, an intermediate-stage carrier amplifier 13, a balun 14, a final-stage (power-stage) carrier amplifier 15, an initial-stage peak amplifier 16, an intermediate-stage peak amplifier 17, a balun 18, a final-stage peak amplifier 19, a coupler 20, a control circuit 21, and bias circuits 22 to 29.

The carrier amplifier 15 is a differential amplifier including a carrier amplifier 15-1 for a first phase and a carrier amplifier 15-2 for a second phase.

The peak amplifier 19 is a differential amplifier including a peak amplifier 19-1 for a first phase and a peak amplifier 19-2 for a second phase.

In the present disclosure, the output signal from an amplifier in a differential amplifier and the output signal from the other amplifier may be different in voltage amplitude from each other by 3 dB or less, and be different in phase from each other in the range between 90° and 270°.

The control circuit 21 includes a variable attenuator 31, an attenuator 32, a detector circuit 33, and a drive-level detection circuit 34.

In the embodiment, the number of stages of the Doherty amplifier circuit 1 is three. However, the present disclosure is not limited to this. The number of stages of the Doherty amplifier circuit 1 may be one or two, or may be four or more.

In the embodiment, each of the carrier amplifier 12 and the carrier amplifier 13 is a single-sided amplifier. However, the present disclosure is not limited to this. Each of the carrier amplifier 12 and the carrier amplifier 13 may be a differential amplifier.

In the embodiment, the carrier amplifier 15 is a differential amplifier. However, the present disclosure is not limited to this. The carrier amplifier 15 may be a single-sided amplifier.

In the embodiment, each of the peak amplifier 16 and the peak amplifier 17 is a single-sided amplifier. However, the present disclosure is not limited to this. Each of the peak amplifier 16 and the peak amplifier 17 may be a differential amplifier.

In the embodiment, the peak amplifier 19 is a differential amplifier. However, the present disclosure is not limited to this. The peak amplifier 19 may be a single-sided amplifier.

The 90° hybrid circuit 11 divides the radio-frequency signal RFin, which is received at the input terminal 1a, into radio-frequency signals RF11 and RF21 having phases different from each other by approximately 90°. The 90° hybrid circuit 11 outputs the radio-frequency signal RF11 to the carrier amplifier 12 and the variable attenuator 31, and outputs the radio-frequency signal RF21 to the peak amplifier 16. The term, “approximately 90°”, encompasses not only a phase of 90° but also a phase of 90°±45°.

In this example, the phase of the radio-frequency signal RF21 is delayed by 90° from that of the radio-frequency signal RF11. In this example, the power of the radio-frequency signal RF11 is the same as that of the radio-frequency signal RF21.

The bias circuit 22 provides a bias to the carrier amplifier 12. The carrier amplifier 12 outputs, to the carrier amplifier 13, a radio-frequency signal RF12 obtained by amplifying the radio-frequency signal RF11. The bias circuit 23 provides a bias to the carrier amplifier 13. The carrier amplifier 13 outputs, to a first end of a first winding 14a of the balun 14, a radio-frequency signal RF13 obtained by amplifying the radio-frequency signal RF12.

The first winding 14a of the balun 14 is electrically connected, at a second end thereof, to a power supply voltage Vcc. The balun 14 converts the radio-frequency signal RF13 into a radio-frequency signal RF14 and a radio-frequency signal RF15 which form a differential signal, and outputs the resulting signals from the respective ends of a second winding 14b.

The bias circuit 24 provides a bias to the carrier amplifier 15-1. The carrier amplifier 15-1 outputs, to the coupler 20, a radio-frequency signal RF16 obtained by amplifying the radio-frequency signal RF14. The bias circuit 25 provides a bias to the carrier amplifier 15-2. The carrier amplifier 15-2 outputs, to the coupler 20, a radio-frequency signal RF17 obtained by amplifying the radio-frequency signal RF15.

The bias circuit 26 provides a bias to the peak amplifier 16. The peak amplifier 16 has an enabling terminal 16a for controlling the operating state (radio-frequency signal amplification state) and the non-operating state (radio-frequency signal non-amplification state). The enabling terminal 16a receives a control signal S1 from the detector circuit 33. The peak amplifier 16 is controlled in accordance with the control signal S1 so as to be switched between the operating state and the non-operating state. The control signal S1 may be a voltage signal, or may be a current signal. In the case of the operating state, the peak amplifier 16 outputs, to the peak amplifier 17, a radio-frequency signal RF22 obtained by amplifying the radio-frequency signal RF21. In the case of the non-operating state, the peak amplifier 16 does not amplify the radio-frequency signal RF21.

The bias circuit 27 provides a bias to the peak amplifier 17. The peak amplifier 17 has an enabling terminal 17a for controlling the operating state and the non-operating state. The enabling terminal 17a receives a control signal S2 from the detector circuit 33. The peak amplifier 17 is controlled in accordance with the control signal S2 so as to be switched between the operating state and the non-operating state. The control signal S2 may be a voltage signal, or may be a current signal. In the case of the operating state, the peak amplifier 17 outputs, to a first end of a first winding 18a of the balun 18, a radio-frequency signal RF23 obtained by amplifying the radio-frequency signal RF22. In the case of the non-operating state, the peak amplifier 17 does not amplify the radio-frequency signal RF22.

The first winding 18a of the balun 18 is electrically connected, at a second end thereof, to the power supply voltage Vcc. The balun 18 converts the radio-frequency signal RF23 into a radio-frequency signal RF24 and a radio-frequency signal RF25 which form a differential signal, and outputs the resulting signals from the respective ends of a second winding 18b.

The bias circuit 28 provides a bias to the peak amplifier 19-1. The peak amplifier 19-1 has an enabling terminal 19-1a for controlling the operating state and the non-operating state. The enabling terminal 19-1a receives a control signal S3 from the detector circuit 33. The peak amplifier 19-1 is controlled in accordance with the control signal S3 so as to be switched between the operating state and the non-operating state. The control signal S3 may be a voltage signal, or may be a current signal. In the case of the operating state, the peak amplifier 19-1 outputs, to the coupler 20, a radio-frequency signal RF26 obtained by amplifying the radio-frequency signal RF24. In the case of the non-operating state, the peak amplifier 19-1 does not amplify the radio-frequency signal RF24.

The bias circuit 29 provides a bias to the peak amplifier 19-2. The peak amplifier 19-2 has an enabling terminal 19-2a for controlling the operating state and the non-operating state. The enabling terminal 19-2a receives a control signal S4 from the detector circuit 33. The peak amplifier 19-2 is controlled in accordance with the control signal S4 so as to be switched between the operating state and the non-operating state. The control signal S4 may be a voltage signal, or may be a current signal. In the case of the operating state, the peak amplifier 19-2 outputs, to the coupler 20, a radio-frequency signal RF27 obtained by amplifying the radio-frequency signal RF25. In the case of the non-operating state, the peak amplifier 19-2 does not amplify the radio-frequency signal RF25.

When a current signal is outputted as a control signal, as illustrated in FIG. 1, the detector circuit 33 may output the different control signals S1 to S4 to the peak amplifiers 16, 17, 19-1, and 19-2, respectively. When a voltage signal is outputted as a control signal, the detector circuit 33 may output a common control signal to the peak amplifiers 16, 17, 19-1, and 19-2.

When the peak amplifiers 16, 17, 19-1, and 19-2 are in the non-operating state, the coupler 20 couples the radio-frequency signals RF16 and RF17 together, and outputs the radio-frequency signal RFout. When the peak amplifiers 16, 17, 19-1, and 19-2 are in the operating state, the coupler 20 couples the radio-frequency signals RF16, RF17, RF26, and RF27 to one another, and outputs the radio-frequency signal RFout.

The drive-level detection circuit 34 detects the drive level (operating level) of the carrier amplifier 15 on the basis of the radio-frequency signals RF16 and RF17, and outputs, to the variable attenuator 31, a detection signal S11 indicating the drive level of the carrier amplifier 15. The detection signal S11 may be a signal (inverted signal) which changes in a complementary manner to the drive level of the carrier amplifier 15.

The variable attenuator 31 receives the radio-frequency signal RF11 and the detection signal S11. The variable attenuator 31 may receive the radio-frequency signal RFin instead of the radio-frequency signal RF11.

On the basis of the detection signal S11, the variable attenuator 31 attenuates the radio-frequency signal RF11 for conversion to a differential signal, and outputs, to the attenuator 32, a radio-frequency signal RF31 which is a differential signal. For example, when the detection signal S11 indicates that the carrier amplifier 15 is close to the saturation level, in this example, the variable attenuator 31 attenuates the radio-frequency signal RF11 just by a small extent, and outputs the radio-frequency signal RF31. For example, when the detection signal S11 indicates that the carrier amplifier 15 is far from the saturation level, in this example, the variable attenuator 31 attenuates the radio-frequency signal RF11 by a large extent, and outputs the radio-frequency signal RF31.

In the embodiment, the variable attenuator 31 outputs the differential radio-frequency signal RF31. However, the present disclosure is not limited to this. The variable attenuator 31 may output a single-ended radio-frequency signal. The variable attenuator 31 may be a variable gain amplifier 31. In this case, the variable gain amplifier 31 may be controlled with the amount of amplification (gain), not with the amount of attenuation.

The attenuator 32 attenuates the radio-frequency signal RF31, which is a differential signal, and outputs, to the detector circuit 33, a radio-frequency signal RF32 which is a differential signal.

In the embodiment, the attenuator 32 outputs the differential radio-frequency signal RF32. However, the present disclosure is not limited to this. The attenuator 32 may output a single-ended radio-frequency signal. When the attenuation by the variable attenuator 31 is enough, the attenuator 32 may be omitted.

On the basis of the radio-frequency signal RF32, the detector circuit 33 outputs the control signals S1, S2, S3, and S4 to the peak amplifiers 16, 17, 19-1, and 19-2, respectively. For example, when the amplitude of the radio-frequency signal RF32 is large, in this example, the detector circuit 33 outputs the control signals S1, S2, S3, and S4 for causing the peak amplifiers 16, 17, 19-1, and 19-2 to enter the operating state. For example, when the amplitude of the radio-frequency signal RF32 is small, in this example, the detector circuit 33 outputs the control signals S1, S2, S3, and S4 for causing the peak amplifiers 16, 17, 19-1, and 19-2 to enter the non-operating state.

### (Effects)

In the case of reception of a high-power radio-frequency signal RF11 which is a main cause of saturation of the carrier amplifiers 12, 13, and 15, the control circuit 21 outputs the control signals S1, S2, S3, and S4 to the respective enabling terminals of the peak amplifiers 16, 17, and 19 to activate the peak amplifiers 16, 17, and 19. Thus, the carrier amplifiers 12, 13, and 15 are not saturated.

An important point in this situation is the response speed of the control circuit 21. The control circuit 21, which detects the radio-frequency signal RF11, is capable of making much faster response compared with the case of the technique described in U.S. Patent Application Publication No. 2016/0241209 in which saturation of a carrier amplifier is detected. Therefore, even when the power of the radio-frequency signal RF11 rises in a short time, the control circuit 21 responds to the rise immediately, and activates the peak amplifiers 16, 17, and 19, preventing the carrier amplifiers 12, 13, and 15 from being saturated even momentarily.

However, if the temperature or other surroundings change (for example, when the gains of the carrier amplifiers 12, 13, and 15 rise at an extremely low temperature), the carrier amplifiers 12, 13, and 15 may be saturated even with a low-power radio-frequency signal RF11. To address such a case, the detector circuit 33 detects the drive level of the carrier amplifier 15. When the carrier amplifiers 12, 13, and 15 are close to saturation, even if the power of the radio-frequency signal RF11 is low, the detector circuit 33 activates the peak amplifiers 16, 17, and 19 immediately.

The control circuit 21, which detects the radio-frequency signal RF11, is capable of activating the peak amplifiers 16, 17, and 19 without making the carrier amplifiers 12, 13, and 15 saturated, even when it takes time to detect the drive level of the carrier amplifier 15. Thus, the Doherty amplifier circuit 1 achieves suppression of a decrease of the quality of the radio-frequency signal RFout.

The control circuit 21 may be considered to have a configuration in which a feed-forward operation is performed in accordance with the radio-frequency signal RF11 and in which a feedback operation is performed in accordance with the drive level of the carrier amplifier 15.

### Second Embodiment

In the second embodiment, a peak amplifier having an enabling terminal will be described.

### (Configuration)

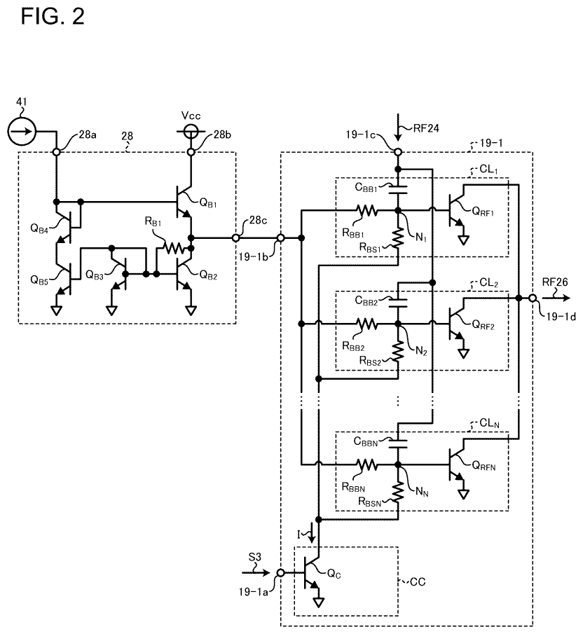

FIG. 2 is a diagram illustrating the configuration of a peak amplifier according to the second embodiment. In FIG. 2, the first-phase peak amplifier 19-1 in the final stage is illustrated as an example of a peak amplifier included in the Doherty amplifier circuit 1. The other peak amplifiers may be configured in substantially the same manner.

The bias circuit 28 receives, at a terminal 28a thereof, a constant current from a constant current source 41. The bias circuit 28 is electrically connected, at a terminal 28b thereof, to the power supply voltage Vcc.

The bias circuit 28 includes transistors Q_{B1}, Q_{B2}, Q_{B3}, Q_{B4}, and Q_{B5} and a resistor R_{B1}.

In the present disclosure, each transistor is a bipolar transistor. However, the present disclosure is not limited to this. In this example, such a bipolar transistor is a heterojunction bipolar transistor (HBT). However, the present disclosure is not limited to this. The transistor may be, for example, a field effect transistor (FET). The transistor may be a multi-finger transistor in which multiple unit transistors are electrically connected in parallel to one another. A unit transistor refers to the minimum configuration of a transistor.

When each transistor is a FET, the source corresponds to the emitter of a bipolar transistor; the gate corresponds to the base of a bipolar transistor; the drain corresponds to the collector of a bipolar transistor.

The collector and base of the transistor Q_{B4} are electrically connected to the terminal 28a. That is, the transistor Q_{B4} is diode-connected.

The collector of the transistor Q_{B5} is electrically connected to the emitter of the transistor Q_{B4}. The emitter of the transistor Q_{B5} is electrically connected to a reference potential. In this example, the reference potential is the ground potential. However, the present disclosure is not limited to this.

The collector of the transistor Q_{B1} is electrically connected to the terminal 28b. The base of the transistor Q_{B1} is electrically connected to the terminal 28a and the collector and base of the transistor Q_{B4}. The emitter of the transistor Q_{B1} is electrically connected to a terminal 28c of the bias circuit 28. The transistor Q_{B1} is a transistor which outputs a bias voltage or a bias current.

The collector of the transistor Q_{B2} is electrically connected to the emitter of the transistor Q_{B1} and the terminal 28c. The emitter of the transistor Q_{B2} is electrically connected to the reference potential.

The resistor R_{B1} is electrically connected, at a first end thereof, to the emitter of the transistor Q_{B1}, the terminal 28c, and the collector of the transistor Q_{B2}. The resistor R_{B1} is electrically connected, at a second end thereof, to the base of the transistor Q_{B2}.

The base and collector of the transistor Q_{B3} are electrically connected to the base of the transistor Q_{B2}, the second end of the resistor R_{B1}, and the base of the transistor Q_{B5}.

The peak amplifier 19-1 receives, at the enabling terminal 19-1a, the control signal S3 from the detector circuit 33 (see FIG. 1). The peak amplifier 19-1 receives, at a terminal 19-1b thereof, the bias current or the bias voltage from the bias circuit 28. The peak amplifier 19-1 receives, at a terminal 19-1c thereof, the radio-frequency signal RF24 from the balun 18 (see FIG. 1). The peak amplifier 19-1 outputs, from a terminal 19-1d thereof, the radio-frequency signal RF26 to the coupler 20 (see FIG. 1)

The peak amplifier 19-1 includes cells CL₁, CL₂, . . . , CL_{N}. That is, the peak amplifier 19-1 is formed of a multi-finger (multi-cell) transistor including multiple cells. However, the present disclosure is not limited to this. The peak amplifier 19-1 may be formed of a single-finger (single-cell) transistor including a single cell.

The peak amplifier 19-1 further includes a state control circuit CC which controls the cells CL₁, CL₂, . . . , CL_{N} to the operating state (radio-frequency signal amplification state) or the non-operating state (radio-frequency signal non-amplification state). The state control circuit CC includes a transistor Q_{C}.

The transistor Q_{C} corresponds to an exemplary “control transistor” in the present disclosure.

The cell CL₁ includes a transistor Q_{RF1}, a capacitor C_{BB1}, and resistors R_{BB1} and R_{BS1}. In this example, the transistor Q_{RF1} is a unit transistor. However, the present disclosure is not limited to this.

The transistor Q_{RF1} corresponds to an exemplary “amplifier transistor” in the present disclosure.

The resistor R_{BB1} is electrically connected, at a first end thereof, to the terminal 19-1b. That is, the resistor R_{BB1} is emitter-follower connected to the transistor Q_{B1} in the bias circuit 28. The resistor R_{BB1} is electrically connected, at a second end thereof, to a node N₁. The capacitor C_{BB1} is electrically connected, at a first end thereof, to the terminal 19-1c. The capacitor C_{BB1} is electrically connected, at a second end thereof, to the node N₁. The base of the transistor Q_{RF1} is electrically connected to the node N₁. The emitter of the transistor Q_{RF1} is electrically connected to the reference potential. The collector of the transistor Q_{RF1} is electrically connected to the terminal 19-1d.

The base of the transistor Q_{RF1} receives the bias current or the bias voltage through the resistor R_{BB1}. The base of the transistor Q_{RF1} receives the radio-frequency signal RF24 through the capacitor C_{BB1}. The transistor Q_{RF1} amplifies the radio-frequency signal RF24, and outputs the radio-frequency signal RF26 from the collector to the terminal 19-1d.

The resistor R_{BS1} is electrically connected, at a first end thereof, to the node N₁. The resistor R_{BS1} is electrically connected, at a second end thereof, to the collector of the transistor Q_{C}.

The cell CL₂ includes a transistor Q_{RF2}, a capacitor C_{BB2}, and resistors R_{BB2} and R_{BS2}. In this example, the transistor Q_{RF2} is a unit transistor. However, the present disclosure is not limited to this. The connection relationship among the transistor Q_{RF2}, the capacitor C_{BB2}, a node N₂, and the resistors R_{BB2} and R_{BS2} is substantially the same as that among the transistor Q_{RF1}, the capacitor C_{BB1}, the node N₁, and the resistors R_{B1} and R_{BS1}, and will not be described.

The transistor Q_{RF2} corresponds to an exemplary “amplifier transistor” in the present disclosure.

The cell CL_{N} includes a transistor Q_{RFN}, a capacitor C_{BBN}, and resistors R_{BBN} and R_{BSN}. In this example, the transistor Q_{RFN} is a unit transistor. However, the present disclosure is not limited to this. The connection relationship among the transistor Q_{RFN}, the capacitor C_{BBN}/a node N_{N}, and the resistors R_{BBN} and R_{BSN} is substantially the same as that of the transistor Q_{RF1}, the capacitor C_{BB1}, the node N₁, and the resistors R_{BB1} and R_{BS1}, and will not be described.

The transistor Q_{RFN} corresponds to an exemplary “amplifier transistor” in the present disclosure.

The collector of the transistor Q_{C} is electrically connected to the second end of the resistor R_{BS1}, the second end of the resistor R_{BS2}, . . . , the second end of the resistor R_{BSN}. The base of the transistor Q_{C} is electrically connected to the enabling terminal 19-1a. The base of the transistor Q_{C} receives the control signal S3. The emitter of the transistor Q_{C} is electrically connected to the reference potential.

Operations of the state control circuit CC will be described.

When the control signal S3 is at the high level, the transistor Q_{C} is in the ON state, and a current I flows from the node N₁, the node N₂, . . . , the node N_{N} through the resistor R_{BS1}, the resistor R_{BS2}, . . . , the resistor R_{BSN}, respectively, to the collector of the transistor Q_{C}. That is, the transistor Q_{C} draws the current I from the node N₁, the node N₂, . . . , the node N_{N}.

A current is drawn from the node N₁ so that a voltage drop occurs in the resistor R_{BB1} through which the drawn current flows, resulting in a drop of the voltage at the node N₁. Therefore, the transistor Q_{RF1}, whose base voltage is dropped, fails to amplify the radio-frequency signal RF24.

Similarly, a current is drawn from the node N₂ so that a voltage drop occurs in the resistor R_{BB2} through which the drawn current flows, resulting in a drop of the voltage at the node N₂. Therefore, the transistor Q_{RF2}, whose base voltage is dropped, fails to amplify the radio-frequency signal RF24.

Similarly, a current is drawn from the node N_{N} so that a voltage drop occurs in the resistor R_{BBN} through which the drawn current flows, resulting in a drop of the voltage at the node N_{N}. Therefore, the transistor Q_{RFN}, whose base voltage is dropped, fails to amplify the radio-frequency signal RF24.

That is, when the control signal S3 is at the high level, the peak amplifier 19-1 is in the non-operating state (radio-frequency signal non-amplification state).

When the control signal S3 is at the low level, the transistor Q_{C} is in the OFF state, and the current I does not flow from the node N₁, the node N₂, . . . , the node N_{N} to the collector of the transistor Q_{C}. That is, the transistor Q_{C} does not draw the current I from the node N₁, the node N₂ . . . , the node N_{N}.

Therefore, the transistor Q_{RF1}, whose base voltage is not dropped, may amplify the radio-frequency signal RF24. Similarly, the transistor Q_{RF2}, whose base voltage is not dropped, may amplify the radio-frequency signal RF24. Similarly, the transistor Q_{RFN}, whose base voltage is not dropped, may amplify the radio-frequency signal RF24.

That is, when the control signal S3 is at the low level, the peak amplifier 19-1 is in the operating state (radio-frequency signal amplification state).

The location of the state control circuit CC may be far from the locations of the cells CL₁, CL₂, . . . , CL_{N}. This is because the current I is less susceptible to influence from a temperature difference. Typically, the detector circuit 33, which is a unit of generating the control signal S3, is disposed at a distance from the peak amplifiers 19-1 and 19-2 which are final-stage amplifiers. Therefore, there often occurs a temperature difference between the detector circuit 33 and the peak amplifiers 19-1 and 19-2 which are apt to become hot because of the demand for a high output power. As a result, the threshold voltage of a transistor disposed near the peak amplifiers 19-1 and 19-2 is apt to become lower than that disposed near the detector circuit 33. Thus, when the state control circuit CC is disposed near the peak amplifiers 19-1 and 19-2, a rise of the temperature near the peak amplifiers 19-1 and 19-2 causes the threshold voltage of the transistor Q_{C}, which is included in the state control circuit CC, to decrease. That is, in the case where the state control circuit CC is disposed near the locations of the cells CL₁, CL₂, . . . , CL_{N}, even when the control signal S3, which is generated by the detector circuit 33, is at the low level, the state control circuit CC may erroneously recognize that “The control signal S3 is at the high level.” In contrast, when the state control circuit CC is disposed far from the locations of the cells CL₁, CL₂, . . . , CL_{N}, a drop of the threshold voltage of the transistor Q_{C} included in the state control circuit CC may be suppressed. Therefore, the erroneous recognition of the state control circuit CC about the control signal S3 is easily prevented. For example, the state control circuit CC may be disposed in the control circuit 21 (see FIG. 1). In this case, the current I may be considered to correspond to the control signal S3.

In contrast, the location of the resistor R_{BB1} may be close to the location of the transistor Q_{RF1}. Voltage is susceptible to influence of parasitic capacitance. If the location of the resistor R_{BB1} is far from the location of the transistor Q_{RF1}, influence of a parasitic capacitance causes a delay of transmission of a voltage drop, which has occurred in the resistor R_{BB1}, to the base of the transistor Q_{RF1}. That is, the transistor Q_{RF1}'s switching between the operating state and the non-operating state is delayed. Therefore, to achieve faster switching of the state of the transistor Q_{RF1}, the location of the resistor R_{BB1} may be close to the location of the transistor Q_{RF1}. The same is true for the other cells.

### (Effects)

For example, like the technique described in U.S. Patent Application Publication No. 2016/0241209, if the bias circuit 28 changes the bias current or the bias voltage to control the operating state (radio-frequency signal amplification state) and the non-operating state (radio-frequency signal non-amplification state) of the peak amplifier 19-1, the switching is delayed. This is because change of a direct current (bias current) or a direct-current voltage (bias voltage) takes time.

In contrast, the enabling terminal 19-1a receives the control signal S3 at the high level or the low level, enabling the peak amplifier 19-1 to control the operating state and the non-operating state. Therefore, the bias circuit 28 does not need to change the bias current or the bias voltage.

Thus, the peak amplifier 19-1 achieves faster switching between the operating state and the non-operating state.

In addition, the state control circuit CC draws the current I from the nodes N₁, N₂, . . . , N_{N}, enabling the peak amplifier 19-1 to control the operating state and the non-operating state of the peak amplifier 19-1.

Thus, the peak amplifier 19-1 may control the operating state and the non-operating state through drawing the current I, achieving faster switching compared with the case of controlling the operating state and the non-operating state through voltage.

### First Modified Example of the Second Embodiment

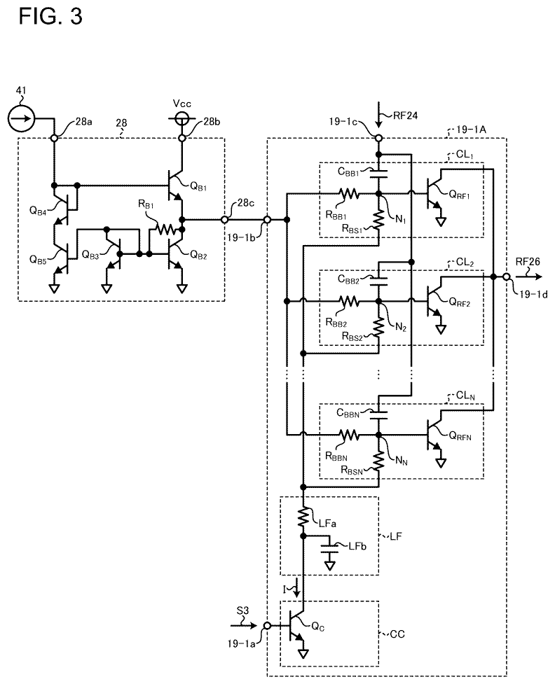

FIG. 3 is a diagram illustrating the configuration of a peak amplifier according to a first modified example of the second embodiment.

A peak amplifier 19-1A further includes a low-pass filter LF compared with the peak amplifier 19-1 (see FIG. 2).

In the embodiment, the low-pass filter LF is an RC low-pass filter including a resistor LFa and a capacitor LFb. However, the present disclosure is not limited to this. The low-pass filter LF may be an LC low-pass filter including an inductor instead of the resistor LFa. However, because the resistor LFa may make the size smaller than an inductor, the resistor LFa rather than an inductor may be used.

The resistor LFa is electrically connected, at a first end thereof, to the second ends of the resistors R_{BS1}, R_{BS2}, . . . , R_{BSN}. The resistor LFa is electrically connected, at a second end thereof, to the collector of the transistor Q_{C}.

The capacitor LFb is electrically connected, at a first end thereof, to the second end of the resistor LFa and the collector of the transistor Q_{C}. The capacitor LFb is electrically connected, at a second end thereof, to the reference potential.

In this example, the cutoff frequency of the low-pass filter LF is less than or equal to the frequency of the radio-frequency signal RF24 or RF26.

Since the resistor LFa is present on a path through which the current I flows, the resistors R_{BS1}, R_{BS2}, . . . , R_{BSN} may be omitted.

The location of the low-pass filter LF may be far from the locations of the cells CL₁, CL₂, . . . , CL_{N}. For example, the low-pass filter LF may be disposed in the control circuit 21 (see FIG. 1).

### Effects of the First Modified Example of the Second Embodiment

The peak amplifier 19-1A, which includes the low-pass filter LF, may suppress occurrence of a leak of the radio-frequency signal RF24 or RF26 to the outside of the peak amplifier 19-1A. Thus, the peak amplifier 19-1A achieves suppression of occurrence of a malfunction of the detector circuit 33 (see FIG. 1) which is caused by the radio-frequency signal RF24 or RF26.

### Second Modified Example of the Second Embodiment

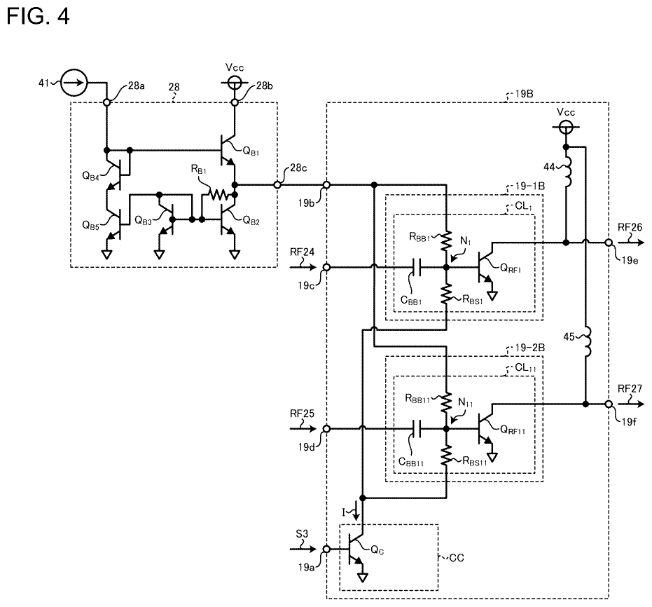

FIG. 4 is a diagram illustrating the configuration of a peak amplifier according to a second modified example of the second embodiment.

A peak amplifier 19B is a differential amplifier. The peak amplifier 19B receives, at an enabling terminal 19a thereof, the control signal S3 from the detector circuit 33 (see FIG. 1). The peak amplifier 19B receives, at a terminal 19b thereof, the bias current or the bias voltage from the bias circuit 28. The peak amplifier 19B receives, at a terminal 19c thereof, the radio-frequency signal RF24. The peak amplifier 19B receives, at a terminal 19d thereof, the radio-frequency signal RF25. The peak amplifier 19B outputs, from a terminal 19e thereof, the radio-frequency signal RF26. The peak amplifier 19B outputs, from a terminal 19f thereof, the radio-frequency signal RF27.

The peak amplifier 19B includes a peak amplifier 19-1B for a first phase, a peak amplifier 19-2B for a second phase, and the state control circuit CC.

The peak amplifier 19-1B includes a single cell CL₁. However, the present disclosure is not limited to this. The peak amplifier 19-1B may include multiple cells.

The peak amplifier 19-2B includes a single cell CL₁₁. However, the present disclosure is not limited to this. The peak amplifier 19-2B may include multiple cells.

The cell CL₁ includes the transistor Q_{RF1}, the capacitor C_{BB1}, and the resistors R_{BB1} and R_{BS1}. In this example, the transistor Q_{RF1} is a unit transistor. However, the present disclosure is not limited to this.

The resistor R_{BB1} is electrically connected, at a first end thereof, to the terminal 19b. That is, the resistor R_{BB1} is emitter-follower connected to the transistor Q_{B1} in the bias circuit 28. The resistor R_{BB1} is electrically connected, at a second end thereof, to the node N₁. The capacitor C_{BB1} is electrically connected, at a first end thereof, to the terminal 19c. The capacitor C_{BB1} is electrically connected, at a second end thereof, to the node N₁. The base of the transistor Q_{RF1} is electrically connected to the node N₁. The emitter of the transistor Q_{RF1} is electrically connected to the reference potential. The collector of the transistor Q_{RF1} is electrically connected to the terminal 19e.

The base of the transistor Q_{RF1} receives the bias current or the bias voltage through the resistor R_{BB1}. The base of the transistor Q_{RF1} receives the radio-frequency signal RF24 through the capacitor C_{BB1}. The collector of the transistor Q_{RF1} receives the power supply voltage Vcc through a choke coil 44. The transistor Q_{RF1} amplifies the radio-frequency signal RF24 and outputs the radio-frequency signal RF26 from the collector to the terminal 19e.

The resistor R_{BS1} is electrically connected, at a first end thereof, to the node N₁. The resistor R_{BS1} is electrically connected, at a second end thereof, to the collector of the transistor Q_{C}.

The cell CL₁₁ includes a transistor Q_{RF11}, a capacitor C_{BB11}, and resistors R_{BB11} and R_{BS11}. In this example, the transistor Q_{RF11} is a unit transistor. However, the present disclosure is not limited to this. The connection relationship among the transistor Q_{RF11}, the capacitor C_{BB11}, a node N₁₁, a choke coil 45, and the resistors R_{BB11} and R_{BS11} is substantially the same as that among the transistor Q_{RF1}, the capacitor C_{BB1}, the node N₁, the choke coil 44, and the resistors R_{BB1} and R_{BS1}, and will not be described.

The collector of the transistor Q_{C} is electrically connected to the second end of the resistor R_{BS1} and the second end of the resistor R_{BS11}. The base of the transistor Q_{C} is electrically connected to the enabling terminal 19a. The base of the transistor Q_{C} receives the control signal S3. The emitter of the transistor Q_{C} is electrically connected to the reference potential.

The location of the state control circuit CC may be far from the locations of the peak amplifiers 19-1 and 19-2. This is because the current I is less susceptible to influence from a parasitic capacitance. For example, the state control circuit CC may be disposed in the control circuit 21 (see FIG. 1). In this case, the current I may be considered to correspond to the control signal S3.

### Effects of the Second Modified Example of the Second Embodiment

The peak amplifier 19B does not need the low-pass filter LF (see FIG. 3). This is because, if the radio-frequency signals RF24 and RF25 leak to the collector of the transistor Q_{C}, the radio-frequency signal RF24 and the radio-frequency signal RF26, which have phases opposite to each other, cancel each other. Therefore, even if the peak amplifier 19B does not include the low-pass filter LF, there is extremely low possibility that the radio-frequency signals RF24 and RF25 leak to the outside of the peak amplifier 19B. Thus, the peak amplifier 19B achieves suppression of occurrence of a malfunction of the detector circuit 33 (see FIG. 1) which is caused by the radio-frequency signal RF24 or RF26.

Since the peak amplifier 19B does not need the capacitor LFb (see FIG. 3) in the low-pass filter LF, the peak amplifier 19B may suppress occurrence of a delay of the current I, achieving faster switching between the operating state and the non-operating state.

### Third Modified Example of the Second Embodiment

As illustrated in FIG. 1, the control circuit 21 controls the switching operation between the operating state and the non-operating state of the final-stage peak amplifier 19. In addition, the control circuit 21 may control the switching operation between the operating state and the non-operating state of at least one of the peak amplifiers 16 and 17 which are disposed preceding to the final stage (on the upstream side of the radio-frequency signal).

If the control circuit 21 exerts control so that at least one of the peak amplifiers 16 and 17 enters the non-operating state, the radio-frequency signals RF24 and RF25 are suppressed. Therefore, the Doherty amplifier circuit 1 achieves suppression of occurrence of a malfunction of the detector circuit 33 which is caused by the radio-frequency signals RF24 and RF25 which leak from the peak amplifier 19.

### Third Embodiment

In the third embodiment, a detector circuit will be described.

### (Configuration)

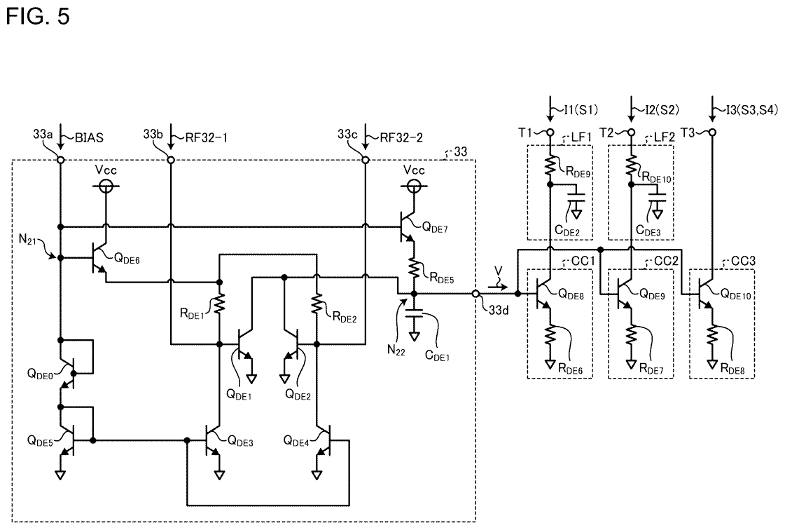

FIG. 5 is a diagram illustrating the configuration of a detector circuit according to the third embodiment.

The detector circuit 33 receives, at a terminal 33a thereof, a bias current BIAS. The detector circuit 33 receives, at a terminal 33b thereof, a radio-frequency signal RF32-1 having a first phase. The detector circuit 33 receives, at a terminal 33c thereof, a radio-frequency signal RF32-2 having a second phase. The detector circuit 33 outputs, from a terminal 33d thereof, a voltage V.

The detector circuit 33 includes transistors Q_{DE0} to Q_{DE7}, resistors R_{DE1}, R_{DE2}, and R_{DE5}, and a capacitor C_{DE1}.

The transistor Q_{DE1} and the transistor Q_{DE2} form a differential pair. The transistors Q_{DE0} and Q_{DE3} to Q_{DE6} and the resistors R_{DE1} and R_{DE2} provide biases to the differential pair.

The transistor Q_{DE7} corresponds to an exemplary “first transistor” in the present disclosure. At least one of the transistors Q_{DE1} and Q_{DE2} corresponds to an exemplary “second transistor” in the present disclosure.

The collector and base of the transistor Q_{DE0} are electrically connected to the terminal 33a through a node N₂₁. That is, the transistor Q_{DE0} is diode-connected. The emitter of the transistor Q_{DE0} is electrically connected to the collector and base of the transistor Q_{DE5}. That is, the transistor Q_{DE5} is diode-connected. The emitter of the transistor Q_{DE5} is electrically connected to the reference potential.

The collector of the transistor Q_{DE0} receives a current from the node N₂₁. The transistor Q_{DE0} and the transistor Q_{DE5} generate a constant voltage. This voltage is the voltage at the node N₂₁. The voltage at the node N₂₁ is received at the base of the transistor Q_{DE6} and the base of the transistor Q_{DE7}.

The collector of the transistor Q_{DE6} is electrically connected to the power supply voltage Vcc. The base of the transistor Q_{DE6} is electrically connected to the node N₂₁. The emitter of the transistor Q_{DE6} is electrically connected to a first end of the resistor R_{DE1} and a first end of the resistor R_{DE2}. The transistor Q_{DE6} outputs a current in accordance with the voltage at the node N₂₁ to the first end of the resistor R_{DE1} and the first end of the resistor R_{DE2}.

The resistor R_{DE1} is electrically connected, at a second end thereof, to the base of the transistor Q_{DE1}. The resistor R_{DE2} is electrically connected, at a second end thereof, to the base of the transistor Q_{DE2}.

The base of the transistor Q_{DE1} is electrically connected to the terminal 33b, and receives the first-phase radio-frequency signal RF32-1. The emitter of the transistor Q_{DE1} is electrically connected to the reference potential. The collector of the transistor Q_{DE1} is electrically connected to a node N₂₂.

The base of the transistor Q_{DE2} is electrically connected to the terminal 33c, and receives the second-phase radio-frequency signal RF32-2. The emitter of the transistor Q_{DE2} is electrically connected to the reference potential. The collector of the transistor Q_{DE2} is electrically connected to the node N₂₂.

The collector of the transistor Q_{DE3} is electrically connected to the second end of the resistor R_{DE1} and the base of the transistor Q_{DE1}. The emitter of the transistor Q_{DE3} is electrically connected to the reference potential. The base of the transistor Q_{DE3} is electrically connected to the base and collector of the transistor Q_{DE5}. That is, the transistor Q_{DE3} and the transistor Q_{DE5} are connected in a current mirror configuration.

The element values of the transistor Q_{DE6}, the resistor R_{DE1}, and the transistor Q_{DE3} are set so that, when the first-phase radio-frequency signal RF32-1 is null, the transistor Q_{DE1} is switched off; when the first-phase radio-frequency signal RF32-1 is not null, the transistor Q_{DE1} operates.

The collector of the transistor Q_{DE4} is electrically connected to the second end of the resistor R_{DE2} and the base of the transistor Q_{DE2}. The emitter of the transistor Q_{DE4} is electrically connected to the reference potential. The base of the transistor Q_{DE4} is electrically connected to the base and collector of the transistor Q_{DE5}. That is, the transistor Q_{DE4} and the transistor Q_{DE5} are connected in a current mirror configuration.

The element values of the transistor Q_{DE6}, the resistor R_{DE2}, and the transistor Q_{DE4} are set so that, when the second-phase radio-frequency signal RF32-2 is null, the transistor Q_{DE2} is switched off; when the second-phase radio-frequency signal RF32-2 is not null, the transistor Q_{DE2} operates.

The collector of the transistor Q_{DE7} is electrically connected to the power supply voltage Vcc. The base of the transistor Q_{DE7} is electrically connected to the node N₂₁. The emitter of the transistor Q_{DE7} is electrically connected to the node N₂₂.

The capacitor C_{DE1} is electrically connected, at a first end thereof, to the node N₂₂. The capacitor C_{DE1} is electrically connected, at a second end thereof, to the reference potential. The capacitor C_{DE1} serves as a low-pass filter which stabilizes the voltage at the node N₂₂. The voltage at the node N₂₂ is the voltage V.

Operations of the detector circuit 33 will be described.

When the first-phase radio-frequency signal RF32-1 and the second-phase radio-frequency signal RF32-2 are null, the transistors Q_{DE1} and Q_{DE2} are switched off. Thus, the collector currents of the transistors Q_{DE1} and Q_{DE2} do not flow. Therefore, a voltage drop in the resistor R_{DE5} does not occur, and the voltage V becomes a voltage close to that at the emitter of the transistor Q_{DE7}. The transistor Q_{DE7} operates as an emitter follower. Thus, the voltage becomes approximately a voltage causing a transistor Q_{DE8}, a transistor Q_{DE9}, and a transistor Q_{DE10} to be switched on.

When the first-phase radio-frequency signal RF32-1 and the second-phase radio-frequency signal RF32-2 are not null, the collector currents of the transistors Q_{DE1} and Q_{DE2} flow, and a voltage drop occurs at the second end of the resistor R_{DE5}, that is, the node N₂₂. Therefore, the voltage V decreases.

As the first-phase radio-frequency signal RF32-1 and the second-phase radio-frequency signal RF32-2 increase, the collector currents of the transistors Q_{DE1} and Q_{DE2} increase. Thus, a larger voltage drop occurs at the second end of the resistor R_{DE5}, that is, the node N₂₂, resulting in a large decrease of the voltage V.

That is, when the first-phase radio-frequency signal RF32-1 and the second-phase radio-frequency signal RF32-2 are null, the detector circuit 33 increases the voltage V to the maximum. The detector circuit 33 decreases the voltage V in accordance with the first-phase radio-frequency signal RF32-1 and the second-phase radio-frequency signal RF32-2.

The voltage V is received by state control circuits CC1, CC2, and CC3.

The state control circuit CC1 includes the transistor Q_{DE8} and a resistor R_{DE6}. The base of the transistor Q_{DE8} is electrically connected to the terminal 33d, and receives the voltage V. The collector of the transistor Q_{DE8} is electrically connected to a low-pass filter LF1. The emitter of the transistor Q_{DE8} is electrically connected to a first end of the resistor R_{DE6}. The resistor R_{DE6} is electrically connected, at a second end thereof, to the reference potential.

The low-pass filter LF1 includes a resistor R_{DE9} and a capacitor C_{DE2}. The resistor R_{DE9} is electrically connected, at a first end thereof, to the collector of the transistor Q_{DE8}. The resistor R_{DE9} is electrically connected, at a second end thereof, to a terminal T1. The terminal T1 is electrically connected to the cells in the initial-stage peak amplifier 16 (see FIG. 1).

When the voltage V is high, that is, when the first-phase radio-frequency signal RF32-1 and the second-phase radio-frequency signal RF32-2 are null, the state control circuit CC1 draws a current I1 from the cells in the initial-stage peak amplifier 16. This causes the initial-stage peak amplifier 16 to enter the non-operating state.

When the voltage V is low, that is, when the first-phase radio-frequency signal RF32-1 and the second-phase radio-frequency signal RF32-2 are not null, the state control circuit CC1 does not draw the current I1 from the cells of the initial-stage peak amplifier 16. This causes the initial-stage peak amplifier 16 to enter the operating state.

The state control circuit CC2 includes the transistor Q_{DE9} and a resistor R_{DE7}. The connection relationship between the transistor Q_{DE9} and the resistor R_{DE7} is substantially the same as that between the transistor Q_{DE8} and the resistor R_{DE6}, and will not be described. A low-pass filter LF2 includes a resistor R_{DE10} and a capacitor C_{DE3}. The resistor R_{DE10} is electrically connected, at a first end thereof, to the collector of the transistor Q_{DE9}. The resistor R_{DE10} is electrically connected, at a second end thereof, to a terminal T2. The terminal T2 is electrically connected to the cells in the intermediate-stage peak amplifier 17 (see FIG. 1).

When the voltage V is high, that is, when the first-phase radio-frequency signal RF32-1 and the second-phase radio-frequency signal RF32-2 are null, the state control circuit CC2 draws a current I2 from the cells in the intermediate-stage peak amplifier 17. This causes the intermediate-stage peak amplifier 17 to enter the non-operating state.

When the voltage V is low, that is, when the first-phase radio-frequency signal RF32-1 and the second-phase radio-frequency signal RF32-2 are not null, the state control circuit CC2 does not draw the current I2 from the cells in the intermediate-stage peak amplifier 17. This causes the intermediate-stage peak amplifier 17 to enter the operating state.

The state control circuit CC3 includes the transistor Q_{DE10} and a resistor R_{DE8}. The connection relationship between the transistor Q_{DE10} and the resistor R_{DE8} is substantially the same as that between the transistor Q_{DE8} and the resistor R_{DE6}, and will not be described.

The collector of the transistor Q_{DE10} is electrically connected to a terminal T3. The terminal T3 is electrically connected to the cells in the final-stage peak amplifier 19 (see FIG. 1).

Since the final-stage peak amplifier 19 is a differential amplifier, as described in the second modified example of the second embodiment, no low-pass filter is needed between the state control circuit CC3 and the final-stage peak amplifier 19.

When the voltage V is high, that is, when the first-phase radio-frequency signal RF32-1 and the second-phase radio-frequency signal RF32-2 are null, the state control circuit CC3 draws a current I3 from the cells in the final-stage peak amplifier 19. This causes the final-stage peak amplifier 19 to enter the non-operating state.

When the voltage V is low, that is, when the first-phase radio-frequency signal RF32-1 and the second-phase radio-frequency signal RF32-2 are not null, the state control circuit CC3 does not draw the current I3 from the cells in the final-stage peak amplifier 19. This causes the final-stage peak amplifier 19 to enter the operating state.

In the embodiment, the detector circuit 33 includes the differential pair (transistors Q_{DE1} and Q_{DE2}). However, the present disclosure is not limited to this. The detector circuit 33 may include the transistor Q_{DE1} or the transistor Q_{DE2}.

When the voltage at the node N₂₂ is stable, the capacitor C_{DE1} may be omitted.

### (Effects)

The detector circuit 33, which is a circuit different from the bias circuits 26 to 29, may suppress influence of the temperatures of the bias circuits 26 to 29, achieving improvement of the temperature characteristics.

The detector circuit 33 changes the collector currents of the transistors Q_{DE1} and Q_{DE2}, which are a differential pair, to output the voltage V. Thus, the detector circuit 33 achieves improvement of the temperature characteristics. In addition, the detector circuit 33 achieves a reduction of the bias voltages of the transistors Q_{DE1} and Q_{DE2}.

### Fourth Embodiment

Among components of a power amplifier circuit according to the fourth embodiment, the same components as those in other embodiments are designated with the same reference numerals, and will not be described.

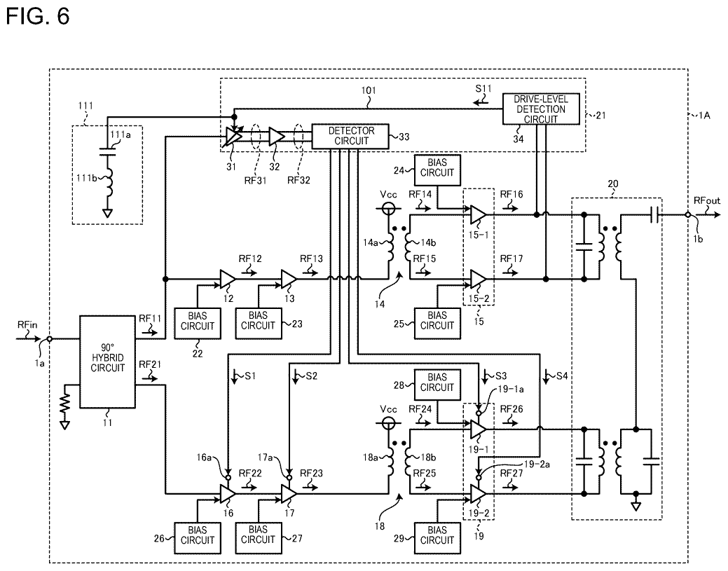

FIG. 6 is a diagram illustrating the configuration of a Doherty amplifier circuit according to the fourth embodiment.

A Doherty amplifier circuit 1A further includes a series resonant circuit 111 compared with the Doherty amplifier circuit 1 (see FIG. 1) according to the first embodiment. The series resonant circuit 111 includes a capacitor 111a and an inductor 111b.

The capacitor 111a is electrically connected, at a first end thereof, to a wiring line 101 extending between the drive-level detection circuit 34 and the variable attenuator 31. The capacitor 111a is electrically connected, at a second end thereof, to a first end of the inductor 111b. The inductor 111b is electrically connected, at a second end thereof, to the reference potential.

The series resonant circuit 111 shunts, for suppression, the signal S11's components of the resonant frequency of the series resonant circuit 111 to the reference potential.

Thus, the Doherty amplifier circuit 1A achieves suppression of an oscillation caused by the feedback loop.

In the present embodiment, the series resonant circuit 111 includes the capacitor 111a and the inductor 111b. However, the present disclosure is not limited to this. The series resonant circuit 111 may have a circuit configuration using a resonator with a piezoelectric element.

If the resonant frequency of the series resonant circuit 111 is low, this may affect the communication quality. Thus, the resonant frequency may be made higher than the modulated-signal bandwidth.

### Fifth Embodiment

Among components of a power amplifier circuit according to the fifth embodiment, the same components as those in other embodiments are designated with the same reference numerals, and will not be described.

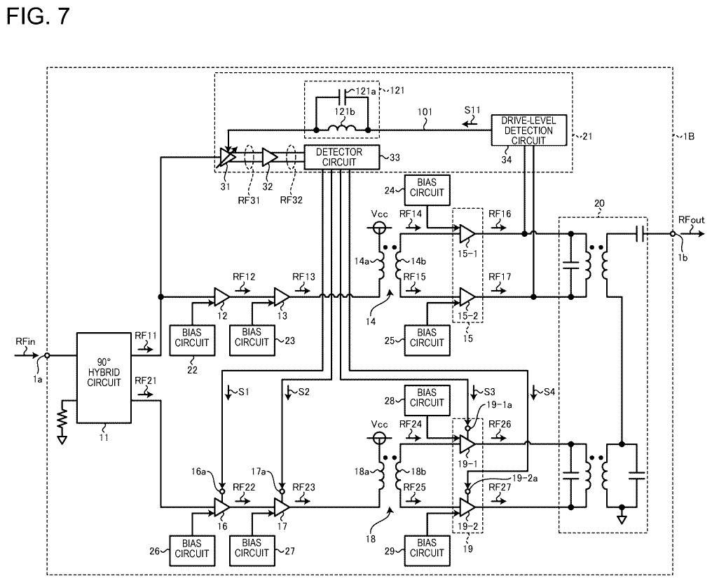

FIG. 7 is a diagram illustrating the configuration of a Doherty amplifier circuit according to the fifth embodiment.

A Doherty amplifier circuit 1B further includes a parallel resonant circuit 121 compared with the Doherty amplifier circuit 1 (see FIG. 1) according to the first embodiment. The parallel resonant circuit 121 includes a capacitor 121a and an inductor 121b.

The inductor 121b is inserted in a series manner on the wiring line 101 extending between the drive-level detection circuit 34 and the variable attenuator 31. The capacitor 121a is electrically connected in parallel to the inductor 121b.

The parallel resonant circuit 121 suppresses the signal S11's components of the resonant frequency of the parallel resonant circuit 121.

Thus, the Doherty amplifier circuit 1B achieves suppression of an oscillation caused by the feedback loop.

In the present embodiment, the parallel resonant circuit 121 includes the capacitor 121a and the inductor 121b. However, the present disclosure is not limited to this. The parallel resonant circuit 121 may have a circuit configuration using a resonator with a piezoelectric element.

If the resonant frequency of the parallel resonant circuit 121 is low, this may affect the communication quality. Thus, the resonant frequency may be made higher than the modulated-signal bandwidth.

### Sixth Embodiment

Among components of a power amplifier circuit according to the sixth embodiment, the same components as those in other components are designated with the same reference numerals, and will not be described.

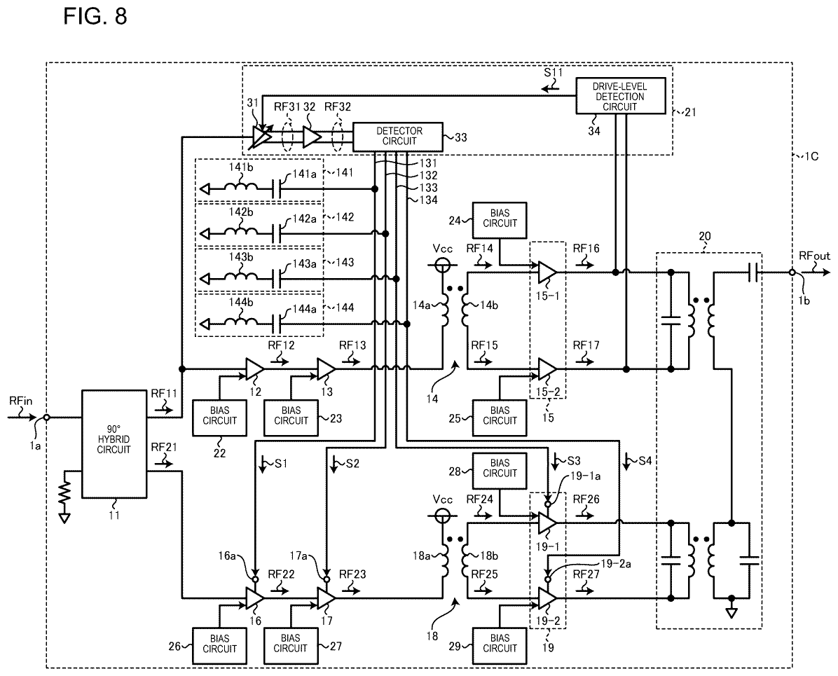

FIG. 8 is a diagram illustrating the configuration of a Doherty amplifier circuit according to the sixth embodiment.

A Doherty amplifier circuit 1C further includes series resonant circuits 141 to 144 compared with the Doherty amplifier circuit 1 (see FIG. 1) according to the first embodiment.

The series resonant circuit 141 includes a capacitor 141a and an inductor 141b. The series resonant circuit 142 includes a capacitor 142a and an inductor 142b. The series resonant circuit 143 includes a capacitor 143a and an inductor 143b. The series resonant circuit 144 includes a capacitor 144a and an inductor 144b.

The capacitor 141a is electrically connected, at a first end thereof, to a wiring line 131 extending between the detector circuit 33 and the peak amplifier 16. The capacitor 141a is electrically connected, at a second end thereof, to a first end of the inductor 141b. The inductor 141b is electrically connected, at a second end thereof, to the reference potential.

The series resonant circuit 141 shunts, for suppression, the signal S1's components of the resonant frequency of the series resonant circuit 141 to the reference potential.

The capacitor 142a is electrically connected, at a first end thereof, to a wiring line 132 extending between the detector circuit 33 and the peak amplifier 17. The capacitor 142a is electrically connected, at a second end thereof, to a first end of the inductor 142b. The inductor 142b is electrically connected, at a second end thereof, to the reference potential.

The series resonant circuit 142 shunts, for suppression, the signal S2's components of the resonant frequency of the series resonant circuit 142 to the reference potential.

The capacitor 143a is electrically connected, at a first end thereof, to a wiring line 133 extending between the detector circuit 33 and the peak amplifier 19-1. The capacitor 143a is electrically connected, at a second end thereof, to a first end of the inductor 143b. The inductor 143b is electrically connected, at a second end thereof, to the reference potential.

The series resonant circuit 143 shunts, for suppression, the signal S3's components of the resonant frequency of the series resonant circuit 143 to the reference potential.

The capacitor 144a is electrically connected, at a first end thereof, to a wiring line 134 extending between the detector circuit 33 and the peak amplifier 19-2. The capacitor 144a is electrically connected, at a second end thereof, to a first end of the inductor 144b. The inductor 144b is electrically connected, at a second end thereof, to the reference potential.

The series resonant circuit 144 shunts, for suppression, the signal S4's components of the resonant frequency of the series resonant circuit 144 to the reference potential.

Thus, the Doherty amplifier circuit 1C achieves suppression of an oscillation caused by the feedback loop.

In the present embodiment, each of the series resonant circuits 141 to 144 includes a capacitor and an inductor. However, the present disclosure is not limited to this. Each of the series resonant circuits 141 to 144 may have a circuit configuration using a resonator with a piezoelectric element.

If the resonant frequency of each of the series resonant circuits 141 to 144 is low, this may affect the communication quality. Thus, the resonant frequency may be made higher than the modulated-signal bandwidth.

### Seventh Embodiment

Among components of a power amplifier circuit according to the seventh embodiment, the same components as those in other embodiments are designated with the same reference numerals, and will not be described.

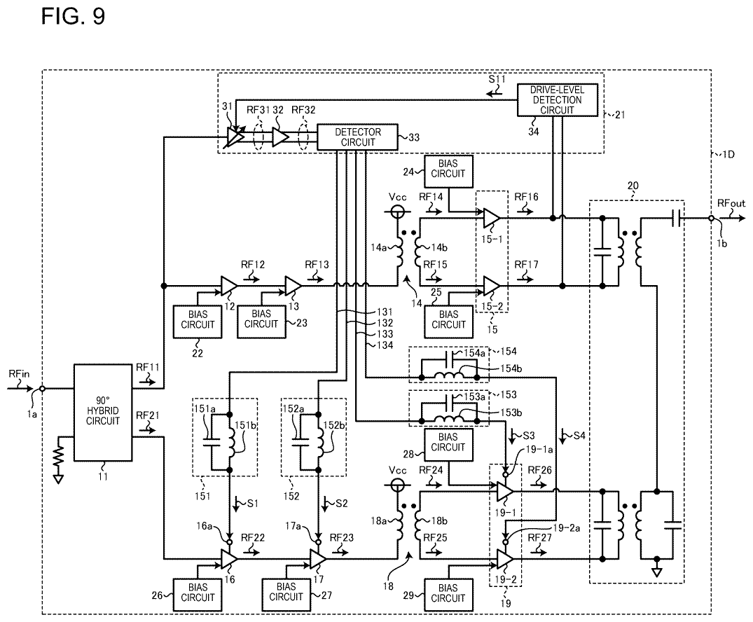

FIG. 9 is a diagram illustrating the configuration of a Doherty amplifier circuit according to the seventh embodiment.

A Doherty amplifier circuit 1D further includes parallel resonant circuits 151 to 154 compared with the Doherty amplifier circuit 1 (see FIG. 1) according to the first embodiment.

The parallel resonant circuit 151 includes a capacitor 151a and an inductor 151b. The parallel resonant circuit 152 includes a capacitor 152a and an inductor 152b. The parallel resonant circuit 153 includes a capacitor 153a and an inductor 153b. The parallel resonant circuit 154 includes a capacitor 154a and an inductor 154b.

The inductor 151b is inserted in a series manner to the wiring line 131 extending between the detector circuit 33 and the peak amplifier 16. The capacitor 151a is electrically connected in parallel to the inductor 151b.

The parallel resonant circuit 151 suppresses the signal S1's components of the resonant frequency of the parallel resonant circuit 151.

The inductor 152b is inserted in a series manner to the wiring line 132 extending between the detector circuit 33 and the peak amplifier 17. The capacitor 152a is electrically connected in parallel to the inductor 152b.

The parallel resonant circuit 152 suppresses the signal S2's components of the resonant frequency of the parallel resonant circuit 152.

The inductor 153b is inserted in a series manner to the wiring line 133 extending between the detector circuit 33 and the peak amplifier 19-1. The capacitor 153a is electrically connected in parallel to the inductor 153b.

The parallel resonant circuit 153 suppresses the signal S3's components of the resonant frequency of the parallel resonant circuit 153.

The inductor 154b is inserted in series manner to the wiring line 134 extending between the detector circuit 33 and the peak amplifier 19-2. The capacitor 154a is electrically connected in parallel to the inductor 154b.

The parallel resonant circuit 154 suppresses the signal S4's components of the resonant frequency of the parallel resonant circuit 154.

Thus, the Doherty amplifier circuit 1D achieves suppression of an oscillation caused by the feedback loop.

In the present embodiment, each of the parallel resonant circuits 151 to 154 includes a capacitor and an inductor. However, the present disclosure is not limited to this. Each of the parallel resonant circuits 151 to 154 may have a circuit configuration using a resonator with a piezoelectric element.

If the resonant frequency of each of the parallel resonant circuits 151 to 154 is low, this may affect the communication quality. Thus, the resonant frequency may be made higher than the modulated-signal bandwidth.

### Configuration Examples of the Present Disclosure

The present disclosure may have the configurations described below.

(1) A Doherty amplifier circuit comprising: a carrier amplifier that amplifies a radio-frequency signal; a peak amplifier that amplifies a radio-frequency signal; and a bias circuit that supplies a bias current or a bias voltage to the peak amplifier, wherein the peak amplifier includes one or more amplifier transistors that amplify a radio-frequency signal, and a state control circuit that controls an operating state of the one or more amplifier transistors on the basis of an input control signal.

(2) The Doherty amplifier circuit according to (1), wherein the state control circuit includes a control transistor that has a base or gate which receives the control signal, that has a collector or drain which is electrically connected to bases or gates of the amplifier transistors, and that has an emitter or source which is grounded.

(3) The Doherty amplifier circuit according to (1) or (2), comprising: one or more resistors, each of the one or more resistors having a first end receiving a bias current or a bias voltage for biasing the one or more amplifier transistors, each of the one or more resistors having a second end electrically connected to a base of a corresponding one of the one or more amplifier transistors.

(4) The Doherty amplifier circuit according to any one of (1) to (3), further comprising: a low-pass filter that is disposed between the state control circuit and the one or more amplifier transistors.

(5) The Doherty amplifier circuit according to (4), wherein the low-pass filter is an RC low-pass filter.

(6) The Doherty amplifier circuit according to any one of (1) to (5), wherein the peak amplifier includes one or more first amplifier transistors that amplify a radio-frequency signal having a first phase, and one or more second amplifier transistors that amplify a radio-frequency signal having a second phase, and wherein the state control circuit controls operating states of the one or more first amplifier transistors and the one or more second amplifier transistors on the basis of the control signal.

(7) The Doherty amplifier circuit according to any one of (1) to (6), comprising: multi-stage peak amplifiers, wherein a final-stage peak amplifier among the multi-stage peak amplifiers is the peak amplifier.

(8) The Doherty amplifier circuit according to (7), wherein a peak amplifier preceding to the final-stage peak amplifier among the multi-stage peak amplifiers is the peak amplifier.

(9) The Doherty amplifier circuit according to any one of (1) to (8), further comprising: a control circuit that outputs the control signal on the basis of a radio-frequency signal and a drive level signal indicating a drive level of the carrier amplifier, wherein the control circuit includes a first transistor that has a collector or drain receiving a power supply voltage, and that has a base or gate receiving a constant voltage, a resistor that has a first end electrically connected to an emitter or source of the first transistor, and a second transistor that has a base or gate receiving a signal obtained by attenuating a radio-frequency signal on the basis of the drive level signal, and that has a collector or drain electrically connected to a second end of the resistor, the second transistor outputting the control signal from the collector.

(10) An amplifier comprising: one or more amplifier transistors that amplify a radio-frequency signal; a bias circuit that supplies a bias current or a bias voltage to the one or more amplifier transistors; and a state control circuit that controls an operating state of the one or more amplifier transistors on the basis of an input control signal.

The embodiments described above are made to facilitate understanding of the present disclosure, not to interpret the present disclosure limitedly. The present disclosure may be changed/improved without departing from the gist thereof, and encompasses the equivalents.
1, 1A, 1B, 1C, 1D Doherty amplifier circuit
11 90° hybrid circuit
12, 13, 15 carrier amplifier
14, 18 balun
16, 17, 19, 19B, 19-1, 19-1A, 19-1B, 19-2, 19-2B peak amplifier
20 coupler
21 control circuit
31 variable attenuator
32 attenuator
33 detector circuit
34 drive-level detection circuit
22, 23, 24, 25, 26, 27, 28, 29 bias circuit
111, 141, 142, 143, 144 series resonant circuit
121, 151, 152, 153, 154 parallel resonant circuit
CL₁, CL₂, . . . , CL_{N}, CL₁₁ cell
CC, CC1, CC2, CC3 state control circuit
LF, LF1, LF2 low-pass filter

1. A Doherty amplifier circuit comprising:
a carrier amplifier that amplifies a first radio-frequency signal;
a peak amplifier that amplifies a second radio-frequency signal; and
a bias circuit that supplies a bias current or a bias voltage to the peak amplifier,
wherein the peak amplifier includes
one or more amplifier transistors that amplify the second radio-frequency signal, and
a state control circuit that controls an operating state of the one or more amplifier transistors on the basis of an input control signal.

2. The Doherty amplifier circuit according to claim 1,
wherein the state control circuit includes
a control transistor that has a base or gate which receives the control signal, that has a collector or drain which is electrically connected to bases or gates of the amplifier transistors, and that has an emitter or source which is grounded.

3. The Doherty amplifier circuit according to claim 1, comprising:
one or more resistors, each of the one or more resistors having a first end receiving a bias current or a bias voltage for biasing the one or more amplifier transistors, each of the one or more resistors having a second end electrically connected to a base of a corresponding one of the one or more amplifier transistors.

4. The Doherty amplifier circuit according to claim 2, comprising:
one or more resistors, each of the one or more resistors having a first end receiving a bias current or a bias voltage for biasing the one or more amplifier transistors, each of the one or more resistors having a second end electrically connected to a base of a corresponding one of the one or more amplifier transistors.

5. The Doherty amplifier circuit according to claim 1, further comprising:
a low-pass filter that is disposed between the state control circuit and the one or more amplifier transistors.

6. The Doherty amplifier circuit according to claim 2, further comprising:
a low-pass filter that is disposed between the state control circuit and the one or more amplifier transistors.

7. The Doherty amplifier circuit according to claim 3, further comprising:
a low-pass filter that is disposed between the state control circuit and the one or more amplifier transistors.

8. The Doherty amplifier circuit according to claim 5,
wherein the low-pass filter is an RC low-pass filter.

9. The Doherty amplifier circuit according to claim 6,
wherein the low-pass filter is an RC low-pass filter.

10. The Doherty amplifier circuit according to claim 7,
wherein the low-pass filter is an RC low-pass filter.

11. The Doherty amplifier circuit according to claim 1,
wherein the peak amplifier includes
one or more first amplifier transistors that amplify the second radio-frequency signal having a first phase, and
one or more second amplifier transistors that amplify a third radio-frequency signal having a second phase, and
wherein the state control circuit controls operating states of the one or more first amplifier transistors and the one or more second amplifier transistors on the basis of the control signal.

12. The Doherty amplifier circuit according to claim 2,
wherein the peak amplifier includes
one or more first amplifier transistors that amplify the second radio-frequency signal having a first phase, and
one or more second amplifier transistors that amplify a third radio-frequency signal having a second phase, and
wherein the state control circuit controls operating states of the one or more first amplifier transistors and the one or more second amplifier transistors on the basis of the control signal.

13. The Doherty amplifier circuit according to claim 2,
wherein the peak amplifier includes
one or more first amplifier transistors that amplify the second radio-frequency signal having a first phase, and
one or more second amplifier transistors that amplify a third radio-frequency signal having a second phase, and
wherein the state control circuit controls operating states of the one or more first amplifier transistors and the one or more second amplifier transistors on the basis of the control signal.

14. The Doherty amplifier circuit according to claim 3,
wherein the peak amplifier includes
one or more first amplifier transistors that amplify the second radio-frequency signal having a first phase, and
one or more second amplifier transistors that amplify a third radio-frequency signal having a second phase, and
wherein the state control circuit controls operating states of the one or more first amplifier transistors and the one or more second amplifier transistors on the basis of the control signal.

15. The Doherty amplifier circuit according to claim 5,
wherein the peak amplifier includes
one or more first amplifier transistors that amplify the second radio-frequency signal having a first phase, and
one or more second amplifier transistors that amplify a third radio-frequency signal having a second phase, and
wherein the state control circuit controls operating states of the one or more first amplifier transistors and the one or more second amplifier transistors on the basis of the control signal.

16. The Doherty amplifier circuit according to claim 8,
wherein the peak amplifier includes
one or more first amplifier transistors that amplify the second radio-frequency signal having a first phase, and
one or more second amplifier transistors that amplify a third radio-frequency signal having a second phase, and
wherein the state control circuit controls operating states of the one or more first amplifier transistors and the one or more second amplifier transistors on the basis of the control signal.

17. The Doherty amplifier circuit according to claim 1, comprising:
multi-stage peak amplifiers,
wherein a final-stage peak amplifier among the multi-stage peak amplifiers is the peak amplifier.

18. The Doherty amplifier circuit according to claim 7,
wherein a peak amplifier preceding to the final-stage peak amplifier among the multi-stage peak amplifiers is the peak amplifier.

19. The Doherty amplifier circuit according to claim 1, further comprising:
a control circuit that outputs the control signal on the basis of the first radio-frequency signal and a drive level signal indicating a drive level of the carrier amplifier,
wherein the control circuit includes
a first transistor that has a collector or drain receiving a power supply voltage, and that has a base or gate receiving a constant voltage,
a resistor that has a first end electrically connected to an emitter or source of the first transistor, and
a second transistor that has a base or gate receiving a signal obtained by attenuating third radio-frequency signal on the basis of the drive level signal, and that has a collector or drain electrically connected to a second end of the resistor, the second transistor outputting the control signal from the collector.

20. An amplifier comprising:
one or more amplifier transistors that amplify a radio-frequency signal;
a bias circuit that supplies a bias current or a bias voltage to the one or more amplifier transistors; and
a state control circuit that controls an operating state of the one or more amplifier transistors on the basis of an input control signal.
